(19) United States
(12) Patent Application Publication
(10) Pub. No.: US 2004/0077174 A1
(43) Pub. Date: Apr. 22, 2004

(54) Method for forming a high aspect ratio via

(75) Inventors: Daniel Yen, Singapore (SG); Wei Hua Cheng, Singapore (SG); Yakub Aliyu, Ridge, NJ (US)

Correspondence Address: WAGNER, MURABITO & HAO LLP, Third Floor, Two North Market Street, San Jose, CA, 95113, US

(73) Assignees: CHARTERED SEMICONDUCTOR MANUFACTURING LTD.; AGILENT TECHNOLOGIES, INC.

(21) Appl. No.: 10/274,668

(22) Filed: Oct. 18, 2002

(51) Int. Cl. H01L 21/311

(52) U.S. Cl. 438/694

(57) ABSTRACT

A method for forming a high aspect ratio via. In one embodiment, the present method comprises providing a first material into which a high aspect ratio via is to be formed. The present embodiment then deposits a first layer of a second material above the first material. Next, the present method recites forming an opening in the first layer of the second material. A second layer of the second material is then deposited above the first layer of the second material and into the opening formed into the first layer of the second material. The present embodiment then etches the second layer of the second material such that the opening extends through the second layer of the second material and through the first layer of the second material. In so doing, the opening is configured to have a profile conducive to the adherence of overlying material thereto. Next, the method of the present embodiment recites etching the first material disposed at the base of the opening such that a portion of the opening extends into the first material. This etching of the first material is performed without substantially etching the second material. In so doing, the present embodiment creates a high aspect ratio via which allows for the formation of a metallized interconnect which is substantially free of voids.

### FIELD OF THE INVENTION

The present claimed invention relates to the field of semiconductor processing. More particularly, the present claimed invention relates to a method for forming high aspect ratio vias.

### BACKGROUND ART

As semiconductor geometries continue to become smaller and smaller, new difficulties arise in the fabrication of the correspondingly smaller features. As one example, when device sizes decrease in size (in order to form more devices on each wafer), features such as vias have critical dimensions (CDs) which become considerably smaller. The reduced CD of, for example, a via has certain drawbacks associated therewith. Referring now to Prior Art FIG. 1A, a side sectional view of a via having a reduced CD is shown. In Prior Art FIG. 1A, a substrate 100 has a via 102 formed therein. In the structure of Prior Art FIG. 1A, the critical dimension (CD) is shown as the width, W, of via 102. Furthermore, it is important to note that the depth, D, of via 102 is much larger than the CD or width, W, of via 102. Hence, via 102 is typically referred to as a high aspect ratio via.

Referring still to Prior Art FIG. 1A, as the CD of via 102 decreases, significant manufacturing difficulties arise. For example, such a high aspect ratio via is typically formed using an anisotropic etch in order to etch a sufficient depth into substrate 100 while still maintaining the desired CD for via 102. As a result, sharp corners, typically shown as 104a and 104b, are formed at the top edge of via 102. Sharp corners 104a and 104b induce stress in subsequently deposited overlying layers and reduce adherence of the overlying layer to underlying substrate 100.

Referring now to Prior Art FIG. 1B, the structure of Prior Art FIG. 1A is shown having a layer of material 106 disposed thereover. Prior Art FIG. 1B illustrates yet another problem associated with conventionally formed high aspect ratio vias. Specifically, due to corner nucleation around sharp corners 104a and 104b, layer of material 106 is not conformally deposited over substrate 100 and into via 102. Instead, a bulging (i.e. a nucleation) of layer of material 106 occurs around corners 104a and 104b, and a seam 108 and/or a void 110 is formed within the portion of layer of material 106 which is deposited into via 102. As will be described below in conjunction with Prior Art FIG. 1C, seam 108 and/or void 110 have significant drawbacks associated therewith.

With reference next to Prior Art FIG. 1C, in typical semiconductor device fabrication processes, subsequent to the deposition of layer of material 106 over underlying substrate 100, a planarization step is performed. This planarization step commonly removes all of layer of material 106 except for that portion which resides within via 102. One conventional planarization method is chemical mechanical polishing (CMP). Unfortunately, seam and/or void 108, often found in conventionally formed high aspect ratio vias, is deleteriously affected by planarization methods such as, for example, CMP. As shown in Prior Art FIG. 1C, seam 108 and/or void 110 may become opened or widened during the CMP process, and slurry or other CMP by-products, typically shown as 112, can be introduced into seam 108 and/or void 110. Such contamination can severely degrade device performance and adversely affect reliability.

As critical dimensions of high aspect ratio vias continue to decrease in size, it is expected that the above-described problems will be further exacerbated. Additionally, any attempts to eliminate or reduce the problems associated with high aspect ratio vias should be compatible with existing semiconductor fabrication processes such that a complete retooling of conventional semiconductor fabrication facilities is not required.

Thus, a need exists for a method for forming a high aspect ratio via wherein the high aspect ratio via does not suffer from poor adherence to a subsequently deposited overlying layer. Still another need exists for a method for forming a high aspect ratio via which enables the formation of a metallized interconnect wherein the method meets the above need and wherein the metallized interconnect does not suffer from void/seam formation. Yet another need exists for a method for forming a high aspect ratio via wherein the method meets all of the above-listed needs and wherein the method is compatible with existing semiconductor fabrication processes.

### SUMMARY OF INVENTION

The present invention provides a method for forming a high aspect ratio via wherein the high aspect ratio via does not suffer from poor adherence to a subsequently deposited overlying layer. The present invention further provides a method for forming a high aspect ratio via which enables the formation of a metallized interconnect wherein the method achieves the above accomplishment and wherein the metallized interconnect does not suffer from void/seam formation. The present invention also provides a method for forming a high aspect ratio via wherein the method achieves all of the above-listed accomplishments and wherein the method is compatible with existing semiconductor fabrication processes.

In one embodiment of the present invention, a method comprises providing a first material into which a high aspect ratio via is to be formed. The present embodiment then deposits a first layer of a second material above the first material. Next, the present method recites forming an opening in the first layer of the second material. A second layer of the second material is then deposited above the first layer of the second material and into the opening formed into the first layer of the second material. The present embodiment then etches the second layer of the second material such that the opening extends through the second layer of the second material and through the first layer of the second material. In so doing, the opening is configured to have a profile conducive to the adherence of overlying material thereto. Next, the method of the present embodiment recites etching the first material disposed at the base of the opening such that a portion of the opening extends into the first material. This etching of the first material is performed without substantially etching the second material. In so doing, the present embodiment creates a high aspect ratio via which allows for the formation of a metallized interconnect which is substantially free of voids.

In another embodiment, the present invention includes the steps of the above-described embodiment, and further includes the step of depositing a layer of a third material (e.g. tungsten) above the second layer of the second material and into the opening having the profile conducive to the adherence of overlying material thereto. After the deposition of the third material, the present embodiment performs a planarization step to remove material disposed above the first material such that the second material is removed and such that the third material remains only in the portion of the opening extending into the first material. As a result, the present embodiment provides a metallized interconnect within a high aspect ratio via, wherein the metallized interconnect is substantially free of voids.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings, which are incorporated in and form a part of this specification, illustrates embodiments of the invention and, together with the description, serve to explain the principles of the invention:

PRIOR ART FIG. 1A is a side sectional view of a high aspect ratio via formed into a substrate wherein the high aspect ratio via has a small critical dimension.

PRIOR ART FIG. 1B is a side sectional view of the structure of PRIOR ART FIG. 1A having a layer of material disposed thereover.

PRIOR ART FIG. 1C is a side sectional view of the structure of PRIOR ART FIG. 1B subsequent to the performance of a planarization process to remove the overlying layer of material except from within the via.

FIG. 2A is a side sectional view of a starting step in a method to form a void-free high aspect ratio via in accordance with one embodiment of the present claimed invention.

FIG. 2B is a side sectional view of the structure of FIG. 2A having a layer of photoresist disposed thereover in accordance with one embodiment of the present claimed invention.

FIG. 2C is a side sectional view of the structure of FIG. 2B having an opening formed in the layer of photoresist in accordance with one embodiment of the present claimed invention.

FIG. 2D is a side sectional view of the structure of FIG. 2C having an opening formed through the layer of photoresist and through the underlying layer in accordance with one embodiment of the present claimed invention.

FIG. 2E is a side sectional view of the structure of FIG. 2D with the layer of photoresist removed therefrom in accordance with one embodiment of the present claimed invention.

FIG. 2F is a side sectional view of the structure of FIG. 2E with an additional layer of material disposed thereover in accordance with one embodiment of the present claimed invention.

FIG. 2G is a side sectional view of the structure of FIG. 2F after an etching step has been performed on the additional layer of material in accordance with one embodiment of the present claimed invention.

FIG. 2H is a side sectional view of the structure of FIG. 2G after an etching step has been performed to create a via in accordance with one embodiment of the present claimed invention.

FIG. 2I is a side sectional view of the structure of FIG. 2H after material has been deposited into the via and over the remaining portion of the structure in accordance with one embodiment of the present claimed invention.

FIG. 2J is a side sectional view of the structure of FIG. 2I after a planarizing step has been performed in accordance with one embodiment of the present claimed invention.

FIG. 3 is a flow chart of steps performed in accordance with one embodiment of the present claimed invention.

FIG. 4 is a flow chart of steps performed in accordance with another embodiment of the present claimed invention.

The drawings referred to in this description should be understood as not being drawn to scale except if specifically noted.

### DESCRIPTION OF THE PREFERRED EMBODIMENTS

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

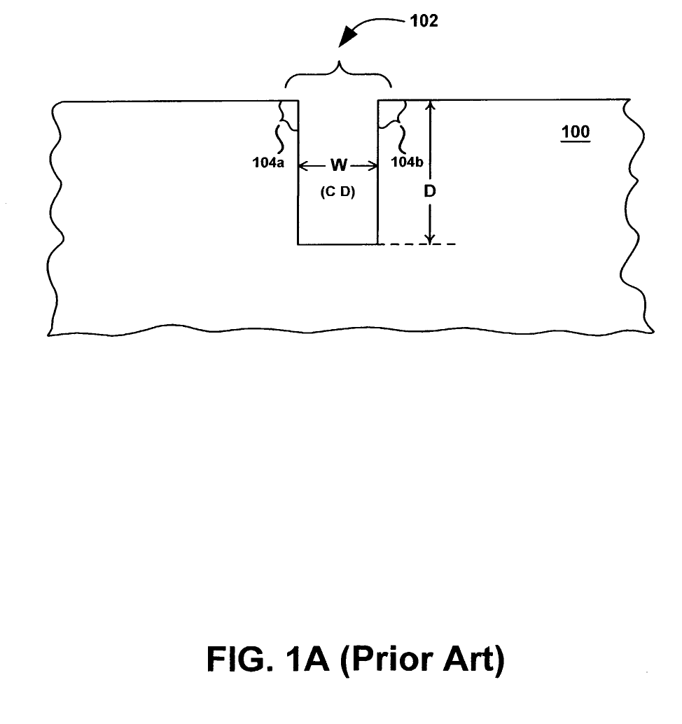

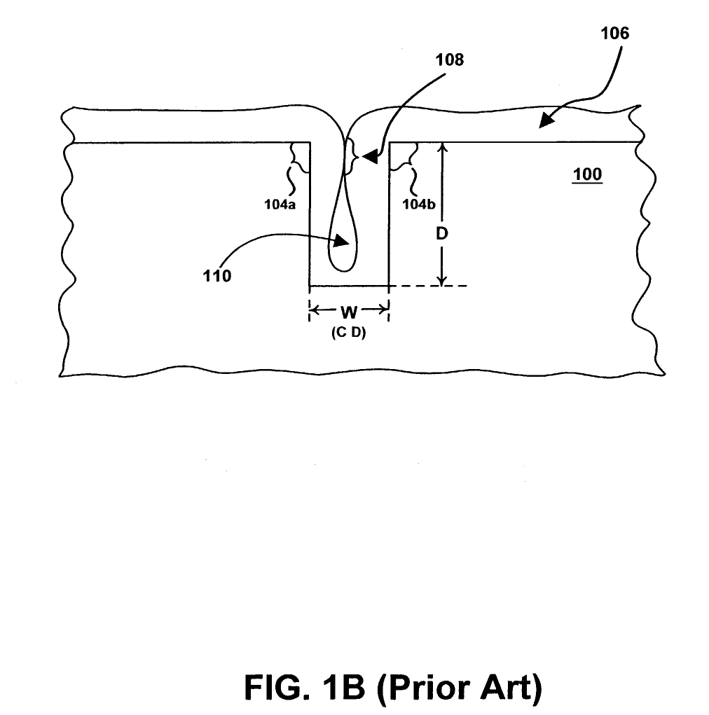

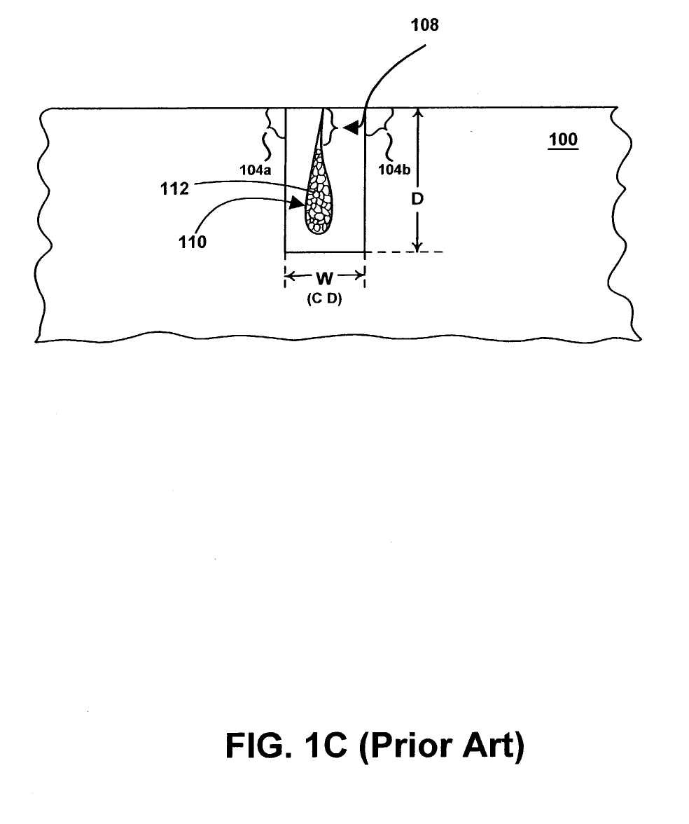

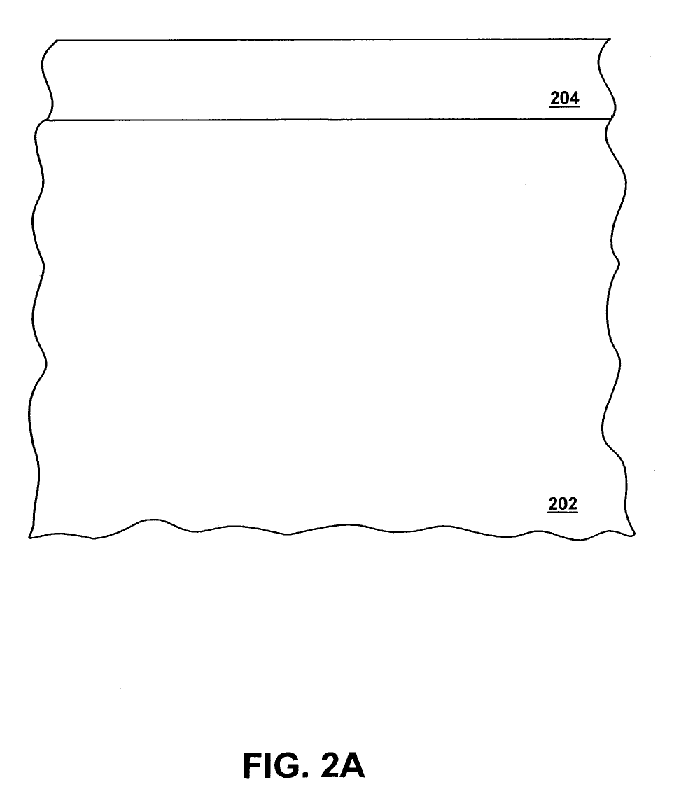

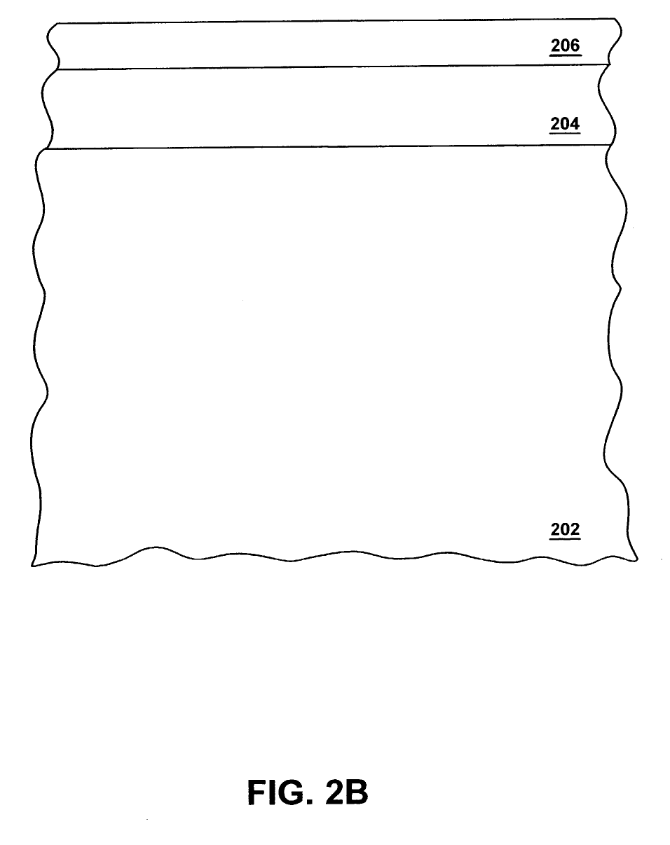

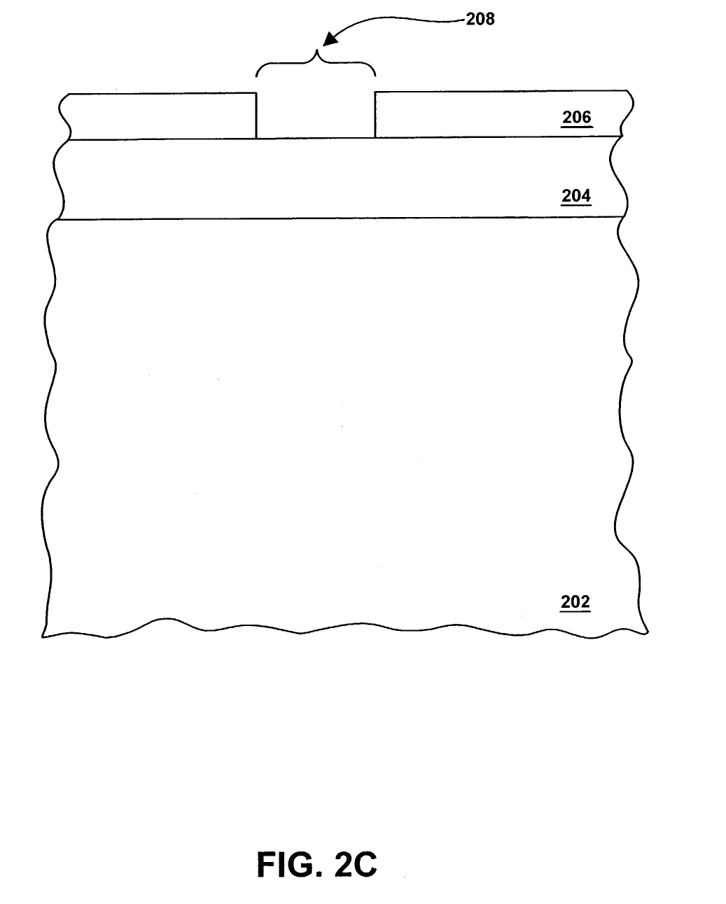

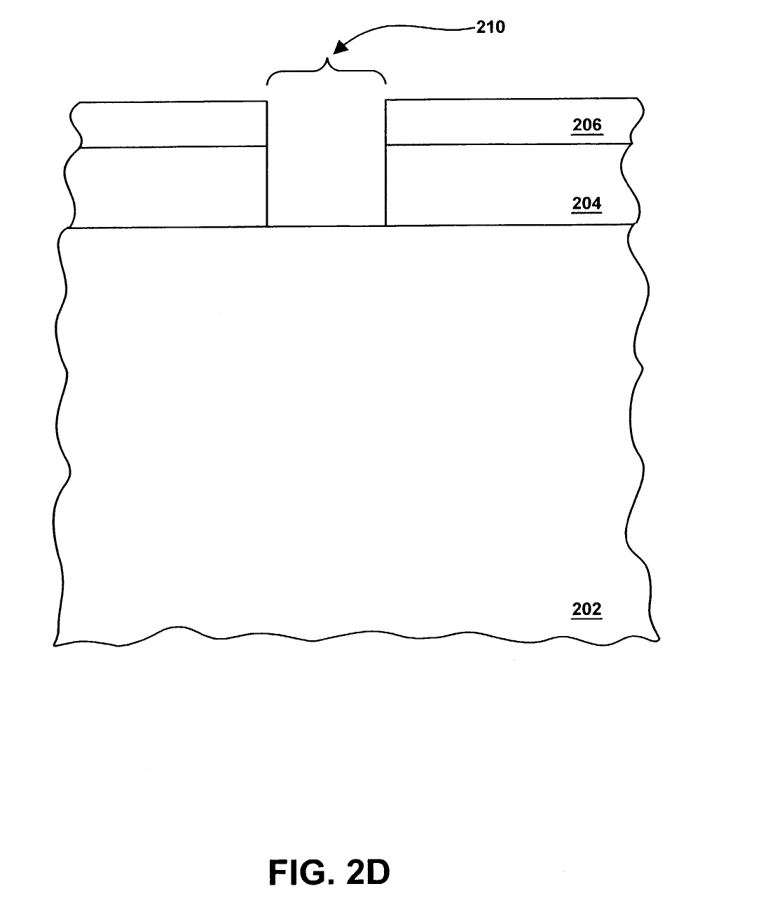

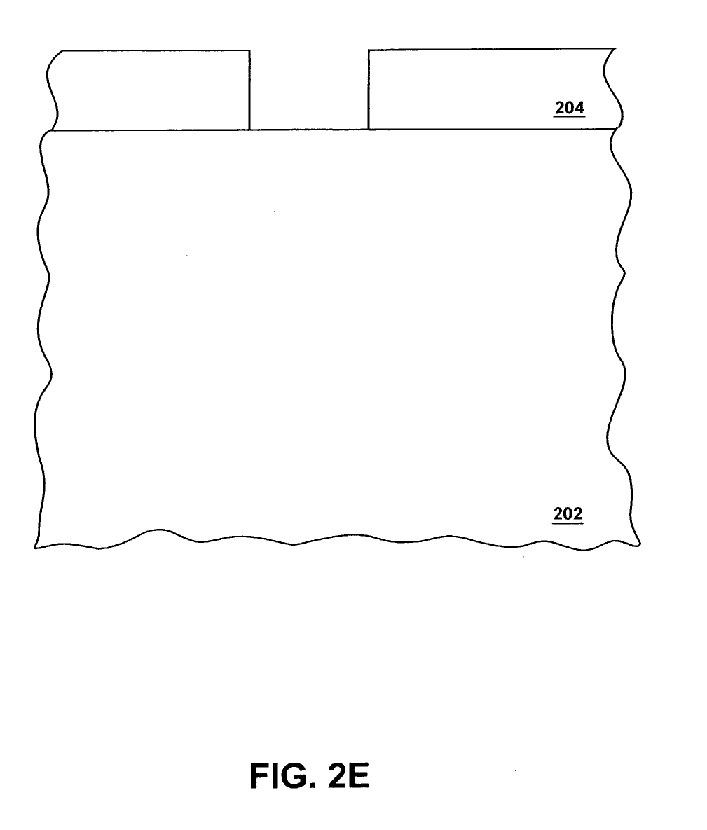

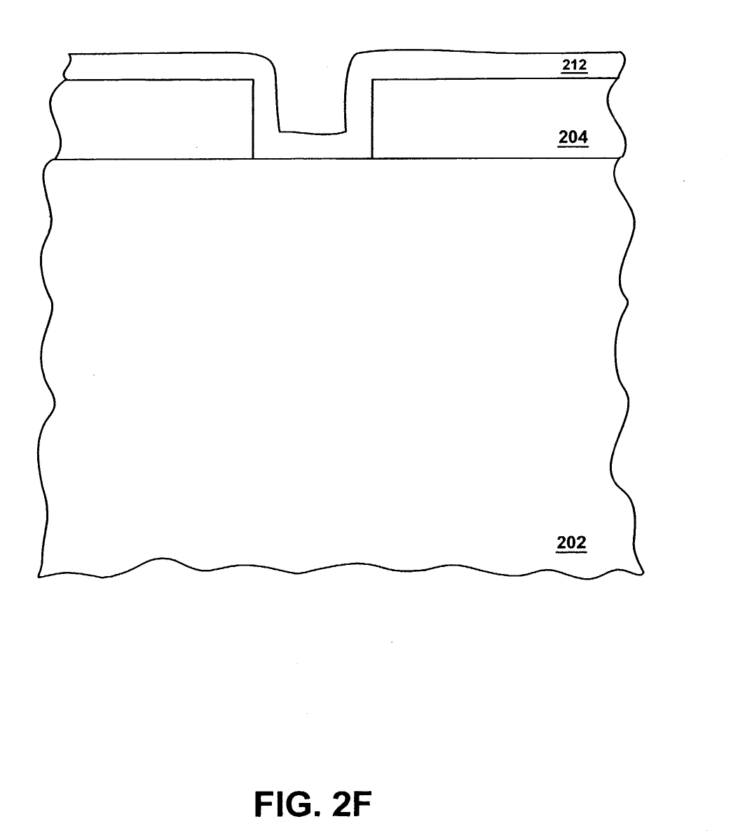

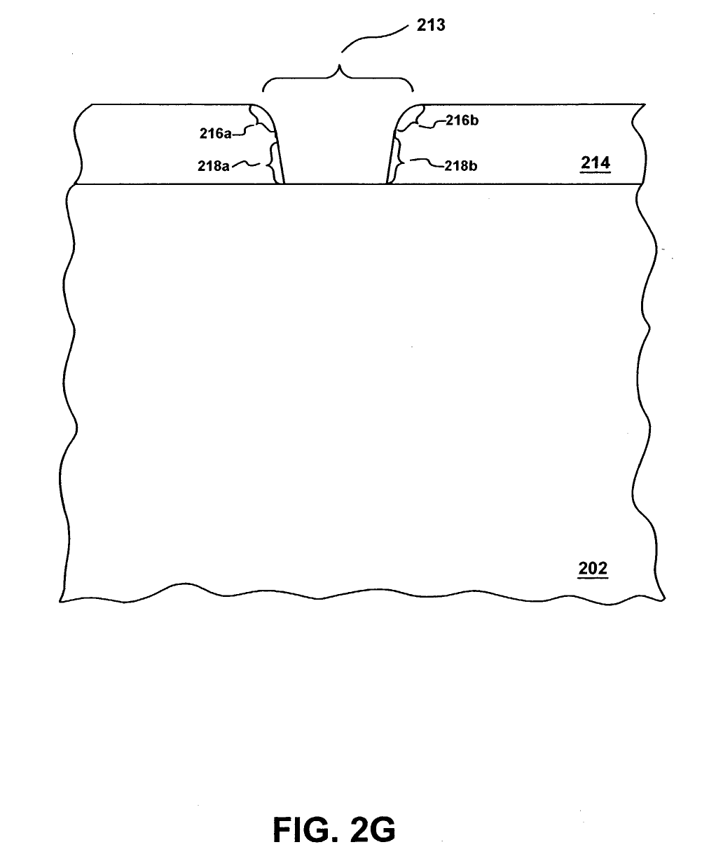

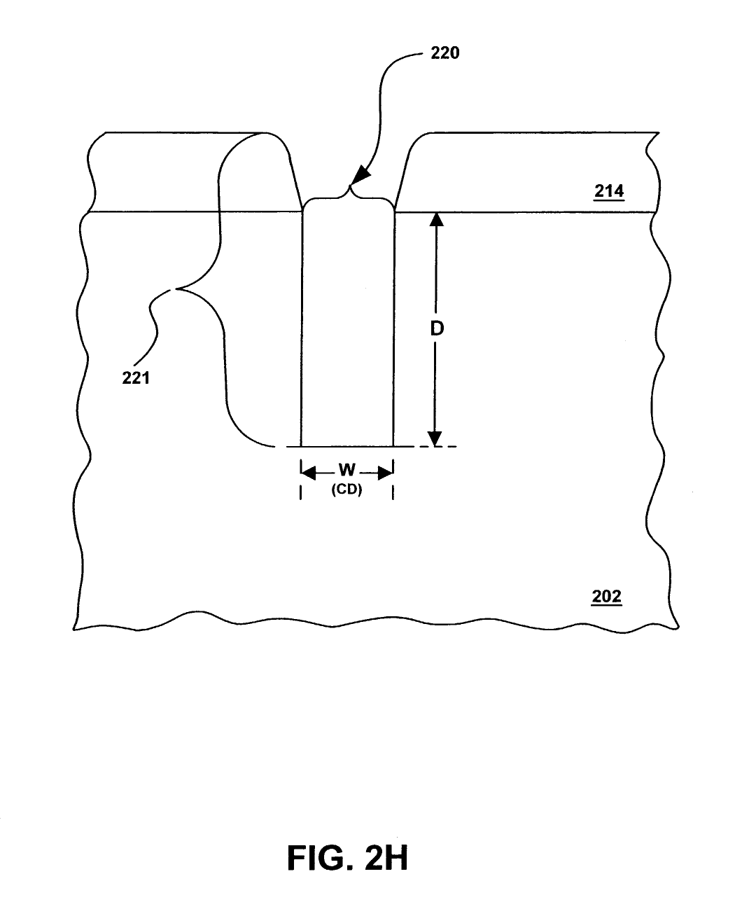

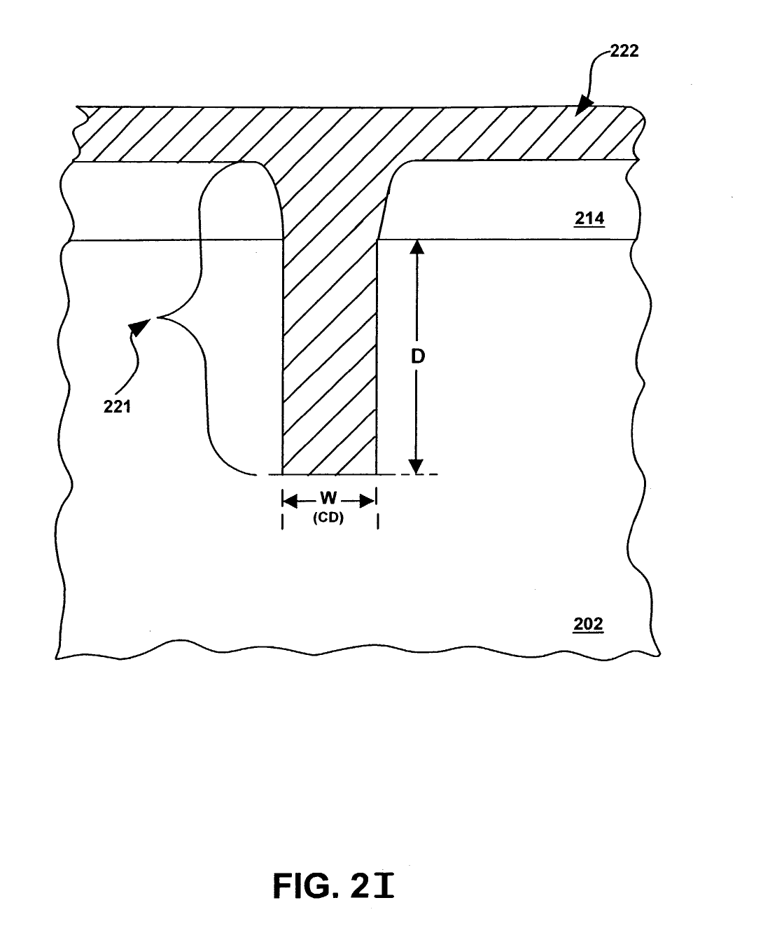

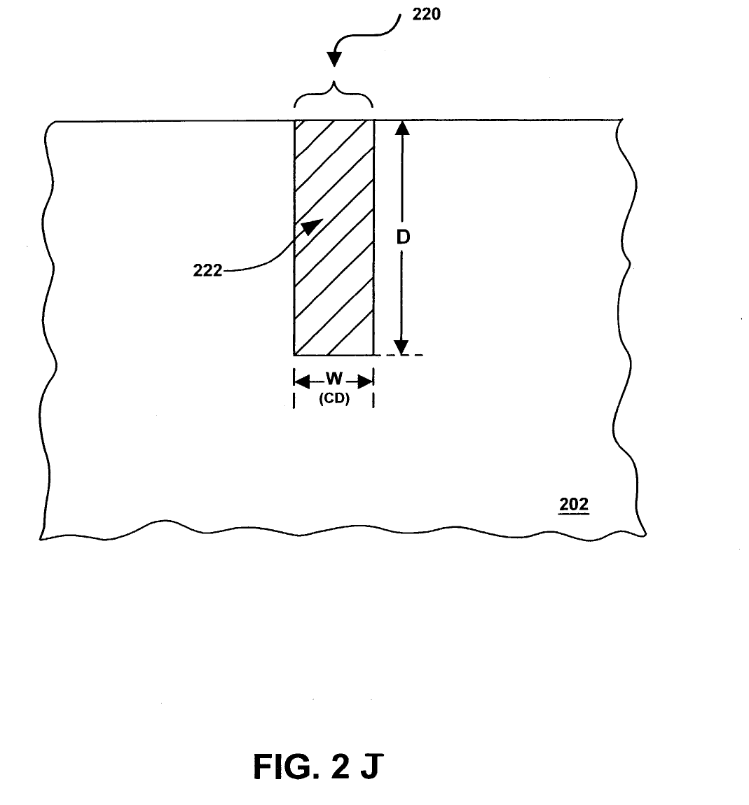

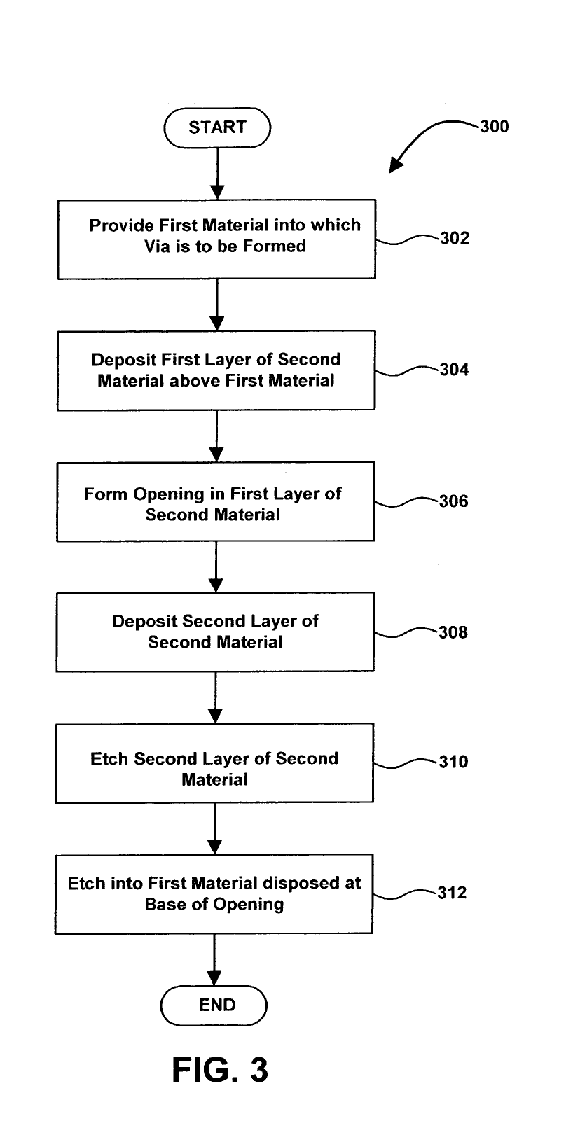

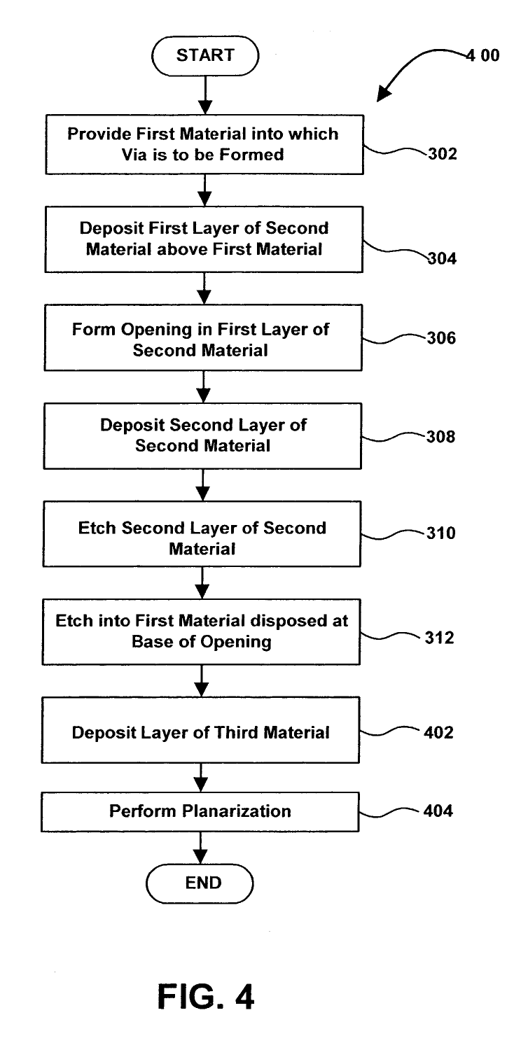

FIGS. 2A-2J provide side sectional views of the structure created according to embodiments of the method of the present invention as set forth in the flow charts of FIGS. 3 and 4. For purposes of clarity, the following discussion will utilize the side sectional views of FIGS. 2A-2J in conjunction with the flow charts of FIGS. 3 and 4 to clearly describe the embodiments of the present invention. Flow chart 300 of FIG. 3 begins with step 302. At step 302, the present embodiment provides a first material into which a via is to be formed. As will be described in detail below, the via to be formed in accordance with the present embodiment is a high aspect ratio via which, unlike conventional high aspect ratio vias, will not induce the formation of voids and/or seams in the material subsequently deposited therein.

Referring still to step 302 of FIG. 3, in the present embodiment, the first material is any material into which it is desired to form a via. As will be understood, such vias are often formed to electrically couple conductive features (e.g. metal 1 and metal 2 layers) which are separated by a dielectric material. In the present embodiment, first material 202 as shown in FIG. 2A is comprised of an intermetal dielectric (IMD) material such as, for example, silicon dioxide. Although such an IMD material is recited in the present embodiment, the present embodiment is well suited to the use of any other material into which it is desired to form a high aspect ratio via. Other materials which are well suited for use as the first material include, but are not limited to, tetraethylorthosilicate (TEOS), fluorine-doped TEOS, and the like.

At step 304 of FIG. 3, the present embodiment recites depositing a first layer 204 of a second material above first material 202 of FIG. 2A. In the present embodiment, first layer 204 of the second material of FIG. 2A is comprised of a material which has an etch selectivity with respect to first material 202. That is, first layer 204 of the second material is comprised of a material that can be etched using an etching process wherein the etching process does not significantly etch first material 202. Similarly, first material 202 is comprised of a material that can be etched using a different etching process wherein the different etching process does not significantly etch first layer 204 of the second material. In one embodiment, first layer 204 of the second material is comprised of an organic-based spin-on-glass material (e.g. HSQ, MSQ, and the like) which has an etch selectivity with respect to first material 202. Although such a material is recited in the present embodiment, the present embodiment is well suited to the use of any other material for first layer 204 of the second material as long as the material has an etch selectivity with respect to first material 202.

Referring still to FIG. 304, in one embodiment of the present invention, a dielectric stop layer 203 is also formed above first material 202 before the deposition of subsequent layers (e.g. layer 204 described below in detail).

At step 306, the present embodiment then forms an opening into first layer 204 of the second material. More specifically, in one embodiment of the present invention, the opening is formed in first layer 204 of the second material by first depositing a layer of photosensitive material such as, for example, layer 206 of photoresist as shown in FIG. 2B, above first layer 204 of the second material. Next, as shown in FIG. 2C, the present embodiment removes a portion 208 of layer 206 of photoresist such that an exposed area of first layer 204 of the second material is produced at a region beneath which a high aspect ratio via is to be formed.

As shown in FIG. 2D, the present embodiment then subjects the exposed area of first layer 204 of the second material to an etching operation such that opening 210 is formed in first layer 204 of the second material. Furthermore, in one embodiment, opening 210 is formed in first layer 204 of the second material such that opening 210 extends through first layer 204 of the second material to the top surface of dielectric stop layer 203. As a result, opening 210 does not substantially etch first material 202. Referring now to FIG. 2E, in this embodiment, step 306 is completed by removing remaining regions of layer 206 of photoresist which reside above first layer 204 of the second material.

Next, as recited at step 308 of FIG. 3, the present embodiment deposits a second layer 212 of FIG. 2F of the second material above first layer 204 of the second material and into opening 210 formed into first layer 204 of the second material. In the present embodiment, second layer 212 of the second material, like first layer 204 of the second material, is comprised of a conformal material which has an etch selectivity with respect to first material 202 such as, for example, the aforementioned organic-based spin-on-glass material (e.g. HSQ, MSQ, and the like). Additionally, in the present embodiment, second layer 212 of the second material is deposited to a depth which corresponds to the critical dimension, CD, of the high aspect ratio via to be formed. For example, in one embodiment, second layer 212 of the second material is deposited to a depth of approximately 10-30 percent of the CD of the high aspect ratio via to be formed. As an example, where the high aspect ratio via is to have a width or CD of 0.5 microns, second layer 212 of the second material will be deposited with a depth of approximately 0.05 to 0.15 microns (i.e. 500 to 1500 Angstroms). Although such a depth for second layer 212 of the second material is recited in the present embodiment, the present embodiment is well suited to depositing second layer 212 of the second material to various greater or lesser depths. More importantly, in the present embodiment, second layer 212 of the second material should conformally cover first layer 204 of the second material and the edges of opening 210.

Referring now to step 310, the present embodiment then etches second layer 212 of the second material such that an opening 213 of FIG. 2G extends through second layer 212 of the second material and through first layer 204 of the second material. Referring now to FIG. 2G, for purposes of clarity, in the structure remaining after step 310, first layer 204 of the second material and second layer 204 of the second material are shown in combination as layer 214. Importantly, in the present embodiment, opening 213 has a profile conducive to the adherence of overlying material thereto. More particularly, hard mask spacer portions 215a and 215b are formed proximate to the edges of opening 213. That is, unlike vias generated using prior via formation methods, opening 213 of the present embodiment has a profile including rounded corners 216a and 216b at the top edge thereof. By having rounded top edge corners 216a and 216b, as opposed to the sharp corners associated with prior art vias, opening 213 does not induce stress in subsequently deposited overlying layers. Hence, opening 213 of the present embodiment does not deleteriously reduce adherence of overlying layers thereto. Additionally, in the present embodiment, unlike vias generated using prior via formation methods, opening 213 of the present embodiment has a profile including sloped sidewalls 218a and 218b. By having sloped sidewalls 218a and 218b, as opposed to the vertical sidewalls associated with prior art vias, opening 213 readily accommodates the adherence of overlying materials thereto. Hence, opening 213 of the present embodiment does not deleteriously reduce adherence of overlying layers thereto.

Referring still to step 310, in one embodiment, opening 213 is formed such that opening 213 extends through layer 214 of the second material to the top surface of dielectric stop layer 203 without substantially etching first material 202. That is, in one embodiment, opening 213 formed at step 310 of FIG. 3 extends completely through layer 214 of the second material and ends at the top surface of dielectric stop layer 203.

With reference now to step 312 of FIG. 3, the present embodiment then completes the formation of the high aspect ratio via by etching through dielectric stop layer 203. Next, in this embodiment, a new etch environment is used to then etch into first material 202. More specifically, the present embodiment etches into that portion of first material 202 which is disposed at the base 220 of opening 213. In so doing, a high aspect ratio via 221 is formed in accordance with one embodiment of the present claimed invention. As mentioned above, high aspect ratio via 221 is referred to as such because the width or CD is considerably smaller than the depth, D, of the via.

Referring still to step 312 of FIG. 3, in this embodiment, high aspect ratio via 221 is formed by subjecting the structure of FIG. 2G to an etching process which etches first material 202 without substantially etching second material 214. Although not shown in FIG. 2H for purposes of clarity, it will be understood that high aspect ratio via 221 will typically terminate at or near a feature to which it is desired to form an electrical connection (e.g. a metal line, and the like). Importantly, by providing a high aspect ratio via 221 with rounded top edges 216a and 216b, and sloped sidewalls 218a and 218b, high aspect ration via 221, of the present embodiment, does not suffer from poor adherence to a subsequently deposited overlying layer. Also, the high aspect ratio via formation method of the present embodiment is readily manufactured using existing semiconductor fabrication processes. That is, the present high aspect ratio via formation method is compatible with existing semiconductor fabrication processes. Additionally, as will be discussed below in conjunction with another embodiment of the present embodiment, high aspect ratio via 221 of the present embodiment enables the formation of a metallized interconnect which does not suffer from void/seam formation.

With reference now to FIG. 4, a flow chart 400 is shown of steps performed in accordance with another embodiment of the present claimed invention in which a metallized interconnect is formed. As shown in flow chart 400, the method of the present embodiment includes the steps and features of the above-described embodiment (i.e. as recited in steps 302-312, and shown in FIGS. 2A-2H). For purposes of brevity and clarity, a discussion of these steps is not repeated here. The method of the present embodiment includes additional steps 402 and 404 which are described below in detail.

At step 402, as illustrated in FIG. 21, the present embodiment deposits a layer 222 of a third material above the structure of FIG. 2H and into high aspect ratio via 221. Moreover, due to the profile of opening 221 as described above in detail, layer 222 of the third material adheres strongly to the edges of opening 221. That is, because opening 221 has rounded top edges 216a and 216b, and sloped sidewalls 218a and 218b, high aspect ration via 221, facilitates adherence of thereto by a subsequently deposited overlying layer (e.g. layer 222 of third material). As a result, the present embodiment does not suffer from corner nucleation (caused in part by sharp opening edges), and subsequent void and/or seam formation in layer 222 of the third material. In one embodiment of the present invention, layer 222 of third material is comprised of a conductive metallic layer such as, for example, tungsten. Although such a conductive material is recited in the present embodiment, the present embodiment is well suited to the use of any other conductive material from which it is desired to form a metallized interconnect. Other materials which are well suited for use as the third material include, but are not limited to, aluminum, copper, various alloys, and the like.

At step 404, the present embodiment completes the formation of the metallized interconnect by performing a planarization step to remove material disposed above dielectric stop layer 203 such that second material 214 is removed and such that third material 222 remains only in that portion of opening 221 which extends into first material 202. As a result, the present embodiment provides a metallized interconnect which is substantially free of the voids and/or seams associated with metallized interconnects formed in conjunction with conventionally fabricated high aspect ratio vias.

Thus, the present invention provides a method for forming a high aspect ratio via wherein the high aspect ration via does not suffer from poor adherence to a subsequently deposited overlying layer. The present invention further provides a method for forming a high aspect ratio via which enables the formation of a metallized interconnect wherein the method achieves the above accomplishment and wherein the metallized interconnect does not suffer from void/seam formation. The present invention also provides a method for forming a high aspect ratio via wherein the method achieves all of the above-listed accomplishments and wherein the method is compatible with existing semiconductor fabrication processes.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications are suited to the particular use contemplated. It is intended that the scope of the invention be defined by the Claims appended hereto and their equivalents.

1. A method for forming a high aspect ratio via, said method comprising the steps of:
a) providing a first material into which said high aspect ratio via is to be formed;
b) depositing a first layer of a second material above said first material;
c) forming an opening in said first layer of said second material;
d) depositing a second layer of said second material above said first layer of said second material and into said opening formed into said first layer of said second material; and
e) etching said second layer of said second material such that said opening extends through said second layer of said second material and through said first layer of said second material, and such that said opening has a profile conducive to the adherence of overlying material thereto; and
f) etching said first material disposed at the base of said opening such that a portion of said opening extends into said first material, said etching of said first material performed without substantially etching said second material.

2. The method for forming a high aspect ratio via as recited in claim 1 further comprising the steps of:
g) depositing a layer of a third material above said second layer of said second material and into said opening remaining after step f) such that said third material adheres to edges of said opening; and
h) performing a planarization step to remove material disposed above said first material such that said second material is removed and such that said third material remains only in said portion of said opening extending into said first material.

3. The method for forming a high aspect ratio via as recited in claim 1, wherein step a) comprises providing a first material, comprised of intermetal dielectric, into which said via is to be formed.

4. The method for forming a high aspect ratio via as recited in claim 1, wherein said first material has an etch selectivity with respect to said second material such that said first material can be etched using a first etch process wherein said first etch process does not significantly etch said second material.

5. The method for forming a high aspect ratio via as recited in claim 1, wherein step c) comprises forming said opening in said first layer of said second material such that said opening extends through said first layer of said second material to said first material without substantially etching said first material.

6. The method for forming a high aspect ratio via as recited in claim 1, wherein step c) comprises forming said opening in said first layer of said second material by performing the steps of:
c1) depositing a layer of photoresist above said first layer of said second material;
c2) removing a portion of said layer of photoresist from said first layer of said second material such that an exposed area of said first layer of said second material is produced at a region beneath which said high aspect ratio via is to be formed;
c3) subjecting said exposed area of said first layer of said second material to an etching operation such that said opening is formed in said first layer of said second material; and
c4) removing remaining regions of said layer of photoresist which reside above said first layer of said second material.

7. The method for forming a high aspect ratio via as recited in claim 1, wherein step e) comprises etching said second layer of said second material such that said opening in said second layer of said second material has a profile including rounded corners at the top edge thereof.

8. The method for forming a high aspect ratio via as recited in claim 1, wherein step e) comprises etching said second layer of said second material such that said opening in said second layer of said second material has a profile including sloped sidewalls.

9. The method for forming a high aspect ratio via as recited in claim 1, wherein step g) comprises depositing a layer of conductive material above said second layer of said second material and into said opening remaining after step f) such that said conductive material adheres to edges of said opening.

10. A method for forming a metallized interconnect within a high aspect ratio via, said method comprising the steps of:
a) providing a dielectric material into which said metallized interconnect within said high aspect ratio via is to be formed;
b) depositing a first layer of a second material above said dielectric material;
c) forming an opening in said first layer of said second material;
d) depositing a second layer of said second material above said first layer of said second material and into said opening formed into said first layer of said second material; and
e) etching said second layer of said second material such that said opening extends through said second layer of said second material and through said first layer of said second material, and such that said opening has a profile conducive to the adherence of overlying material thereto; and
f) etching said dielectric material disposed at the base of said opening such that a portion of said opening extends into said dielectric material, said etching of said dielectric material performed without substantially etching said second material;
g) depositing a layer of metallic material above said second layer of said second material and into said opening remaining after step f) such that said layer of metallic material adheres to edges of said opening; and
h) performing a planarization step to remove material disposed above said dielectric material such that said second material is removed and such that said layer of metallic material remains only in said portion of said opening extending into said dielectric material.

11. The method for forming a metallized interconnect within a high aspect ratio via as recited in claim 10, wherein said dielectric material has an etch selectivity with respect to said second material such that said dielectric material can be etched using a first etch process wherein said first etch process does not significantly etch said second material.

12. The method for forming a metallized interconnect within a high aspect ratio via as recited in claim 10, wherein step c) comprises forming said opening in said first layer of said second material such that said opening extends through said first layer of said second material to said dielectric material without substantially etching said first material.

13. The method for forming a metallized interconnect within a high aspect ratio via as recited in claim 10, wherein step c) comprises forming said opening in said first layer of said second material by performing the steps of:
c1) depositing a layer of photoresist above said first layer of said second material;
c2) removing a portion of said layer of photoresist from said first layer of said second material such that an exposed area of said first layer of said second material is produced at a region beneath which said high aspect ratio via into which said metallized interconnect is to be formed;
c3) subjecting said exposed area of said first layer of said second material to an etching operation such that said opening is formed in said first layer of said second material; and
c4) removing remaining regions of said layer of photoresist which reside above said first layer of said second material.

14. The method for forming a metallized interconnect within a high aspect ratio via as recited in claim 10, wherein step e) comprises etching said second layer of said second material such that said opening in said second layer of said second material has a profile including rounded corners at the top edge thereof.

15. The method for forming a metallized interconnect within a high aspect ratio via as recited in claim 10, wherein step e) comprises etching said second layer of said second material such that said opening in said second layer of said second material has a profile including sloped sidewalls.
